(19) United States
(12) Patent Application Publication
(10) Pub. No.: US 2014/0048868 A1
(43) Pub. Date: Feb. 20, 2014

(54) THREE-DIMENSIONAL SEMICONDUCTOR MEMORY DEVICE AND A METHOD OF MANUFACTURING THE SAME

(71) Applicants: Juhyung Kim, Gyeonggi-do (KR); Yoocheol Shin, Gyeonggi-do (KR)

(72) Inventors: Juhyung Kim, Gyeonggi-do (KR); Yoocheol Shin, Gyeonggi-do (KR)

(21) Appl. No.: 13/966,866

(22) Filed: Aug. 14, 2013

(30) Foreign Application Priority Data
Aug. 20, 2012 (KR) 10-2012-0090849

(51) Int. Cl. H01L 29/792

(52) U.S. Cl. CPC H01L 29/7926
USPC 257/324

(57) ABSTRACT

A three-dimensional (3D) semiconductor memory device may include an electrode structure extending in a first direction and including insulating patterns and horizontal electrodes stacked on a substrate, a semiconductor pillar penetrating the electrode structure and connected to the substrate, a charge storage layer between the semiconductor pillar and the electrode structure, a tunnel insulating layer between the charge storage layer and the semiconductor pillar, and a blocking insulating layer between the charge storage layer and the electrode structure. A first horizontal electrode of the horizontal electrodes includes a gate electrode and a metal stopper between the gate electrode and the blocking insulating layer.

### CROSS-REFERENCE TO RELATED APPLICATION

This U.S. non-provisional patent application claims priority under 35 U.S.C. §119 to Korean Patent Application No. 10-2012-0090849, filed on Aug. 20, 2012, in the Korean Intellectual Property Office, the disclosure of which is incorporated by reference herein in its entirety.

### BACKGROUND

1. Technical Field

The inventive concept relates to semiconductor devices and methods of manufacturing the same and, more particularly, to three-dimensional semiconductor memory devices including vertically stacked memory cells and methods of manufacturing the same.

2. Discussion of the Related Art

Demand for highly integrated semiconductor memory devices has been increasing. To make semiconductor memory devices such as two-dimensional or planar semiconductor memory devices further integrated, fine pattern forming technology may be used. However, even with the high integration density afforded by increased pattern fineness, the capacity of the two-dimensional or planar semiconductor memory devices may be limited by its available area.

To provide more capacity than a two-dimensional or planar semiconductor memory device, three-dimensional semiconductor memory devices having three-dimensionally arranged memory cells have been developed. However, to mass produce three-dimensional semiconductor memory devices, new process technologies are needed.

### SUMMARY

Exemplary embodiments of the inventive concept may provide three-dimensional (3D) semiconductor memory devices capable of improving integration degree and reliability.

Exemplary embodiments of the inventive concept may also provide methods of manufacturing a 3D semiconductor memory device capable of improving integration degree and reliability.

In an exemplary embodiment of the inventive concept, a 3D semiconductor memory device may include: an electrode structure including insulating patterns and horizontal electrodes stacked on a substrate, the electrode structure extending in a first direction; a semiconductor pillar penetrating the electrode structure and connected to the substrate; a charge storage layer between the semiconductor pillar and the electrode structure; a tunnel insulating layer between the charge storage layer and the semiconductor pillar; and a blocking insulating layer between the charge storage layer and the electrode structure. A first horizontal electrode of the horizontal electrodes may include a gate electrode and a metal stopper disposed between the gate electrode and the blocking insulating layer.

In an exemplary embodiment of the inventive concept, the electrode structure may be provided in plural; a trench extending in the first direction may be between the plurality of electrode structures; and the plurality of electrode structures may be spaced apart from each other in a second direction crossing the first direction.

In an exemplary embodiment of the inventive concept, the 3D semiconductor memory device may further include: an isolation insulating layer filling the trench between the plurality of electrode structures.

In an exemplary embodiment of the inventive concept, the tunnel insulating layer, the charge storage layer, and the blocking insulating layer may extend vertically from the substrate.

In an exemplary embodiment of the inventive concept, the metal stopper may be in contact with the blocking insulating layer.

In an exemplary embodiment of the inventive concept, the metal stopper may include a conductive metal nitride.

In an exemplary embodiment of the inventive concept, the gate electrode may include a metal.

In an exemplary embodiment of the inventive concept, the first horizontal electrode may further include a barrier pattern between the metal stopper and the gate electrode.

In an exemplary embodiment of the inventive concept, the semiconductor pillar may have a tube-shape; and may be filled with a filling layer.

In an exemplary embodiment of the inventive concept, the insulating patterns and the horizontal electrodes may be alternately and repeatedly stacked on the substrate.

In an exemplary embodiment of the inventive concept, a method of manufacturing a 3D semiconductor memory device may include: forming a mold stack structure including insulating layers and sacrificial layers alternately and repeatedly stacked on a substrate; forming first and second through-holes penetrating the mold stack structure and exposing the substrate; etching portions of the sacrificial layers exposed by the first and second through-holes to form first recess regions; forming metal stoppers in the first recess regions; forming a vertical structure including a semiconductor pillar in each of the first and second through-holes; forming a trench dividing the mold stack structure into first and second mold stack patterns; removing the sacrificial layers exposed by the trench to form second recess regions; and forming gate electrodes in the second recess regions.

In an exemplary embodiment of the inventive concept, forming the metal stoppers may include: depositing a metal layer in the first and second through-holes and the first recess regions; and isotropically etching the deposited metal layer to form the metal stoppers.

In an exemplary embodiment of the inventive concept, at least one of the metal stoppers may partially fill at least one of the first recess regions; and a portion of the vertical structure may be formed in the at least one first recess region.

In an exemplary embodiment of the inventive concept, forming the vertical structure may include: sequentially forming a blocking insulating layer, a charge storage layer, and a tunnel insulating layer in each of the first and second through-holes; and forming the semiconductor pillar on the tunnel insulating layer in each of the first and second through-holes.

In an exemplary embodiment of the inventive concept, forming the second recess regions may include: etching the sacrificial layers until the metal stoppers are exposed.

In an exemplary embodiment of the inventive concept, the method may further include: forming barrier patterns in the second recess regions before forming the gate electrodes.

In an exemplary embodiment of the inventive concept, a 3D semiconductor memory device may include a first insulating layer and a second insulating layer disposed on a substrate; a gate electrode and a metal stopper disposed between the first and second insulating layers; and a blocking insulating layer, a charge storage layer, a tunnel insulating layer and a semiconductor pillar disposed in sequence, wherein the blocking insulating layer is adjacent to the metal stopper.

The blocking insulating layer may extend from the first insulating layer to the second insulating layer.

A barrier layer may be formed between the metal stopper and the gate electrode.

The blocking insulating layer, the charge storage layer and the tunnel insulating layer may form a data storage element.

### BRIEF DESCRIPTION OF THE DRAWINGS

The above and other features of inventive concept will become more apparent by describing in detail exemplary embodiments thereof with reference to the attached drawings, in which:

FIG. 1A is a circuit diagram illustrating a cell array of a three-dimensional (3D) semiconductor memory device according to an exemplary embodiment of the inventive concept;

FIG. 1B is a perspective view illustrating a structure of a 3D semiconductor memory device according to an exemplary embodiment of the inventive concept;

FIGS. 2 through 8 and 10 through 13 are cross-sectional views illustrating a method of manufacturing a 3D semiconductor memory device according to exemplary embodiments of the inventive concept;

FIGS. 9A and 9B are enlarged views of a portion ‘A’ of FIG. 8;

FIG. 14 is an enlarged-perspective view of a portion ‘B’ of FIG. 13;

FIG. 15 is a block diagram illustrating an electronic system including a 3D semiconductor memory device according to an exemplary embodiment of the inventive concept; and

FIG. 16 is a block diagram illustrating a memory card including a 3D semiconductor memory device according to an exemplary embodiment of the inventive concept.

### DETAILED DESCRIPTION OF THE EMBODIMENTS

Hereinafter, exemplary embodiments of the inventive concept will be described in detail with reference to the accompanying drawings. It should be noted, however, that the inventive concept is not limited to the following exemplary embodiments, and may be embodied in various forms. In the drawings, certain aspects of embodiments of the inventive concept such as sizes of elements may be exaggerated for clarity.

As used herein, the singular forms “a,” “an” and “the” are intended to include the plural forms as well, unless the context clearly indicates otherwise. It will be understood that when an element such as a layer, region or substrate is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present.

The same reference numerals or the same reference designators may denote the same elements throughout the specification and drawings.

A three-dimensional (3D) semiconductor memory device according to an exemplary embodiment of the inventive concept may include a cell array region, a peripheral circuit region, and a connection region. A plurality of memory cells, bit lines, and word lines may be disposed in the cell array region. Peripheral circuits for driving the memory cells and sensing data stored in the memory cells may be formed in the peripheral circuit region. In addition, a word line driver, a sense amplifier, row and column decoders, and control circuits may be disposed in the peripheral circuit region. The connection region may be disposed between the cell array region and the peripheral circuit region. An interconnection structure for electrically connecting the word lines to the peripheral circuits may be disposed in the connection region.

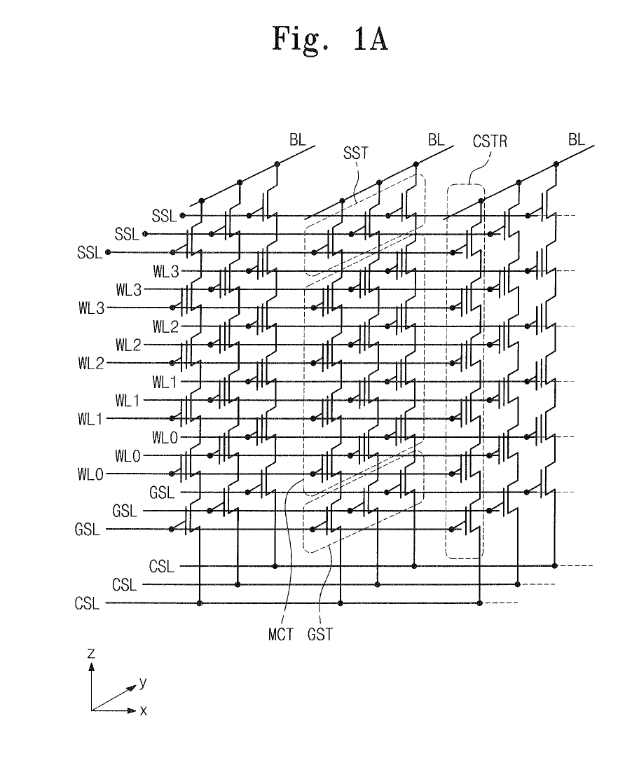

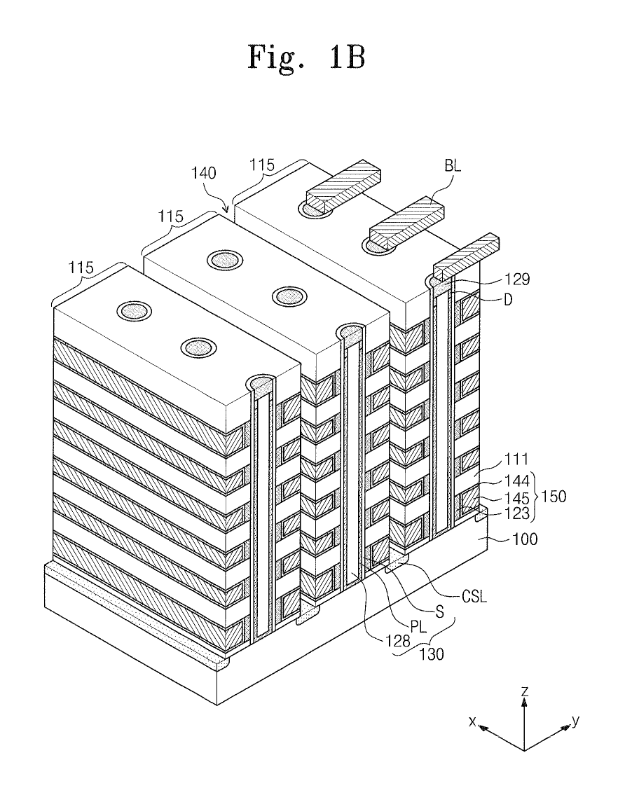

FIG. 1A is a circuit diagram illustrating a cell array of a 3D semiconductor memory device according to an exemplary embodiment of the inventive concept.

Referring to FIG. 1A, a cell array of a 3D semiconductor memory device according to an exemplary embodiment of the inventive concept may include a common source line CSL, a bit line BL, and a plurality of cell strings CSTR disposed between the common source line CSL and the bit line BL.

The bit line BL may be two-dimensionally arranged in plural. A plurality of the cell strings CSTR may be connected in parallel to each of the hit lines BL. The cell strings

CSTR may be connected to the common source line CSL in common. In other words, the plurality of cell strings CSTR may be disposed between the common source line CSL and the bit lines BL. In an exemplary embodiment of the inventive concept, the common source line CSL may be provided in plural, and the plurality of common source lines CSL may be two-dimensionally arranged. The same voltage may be applied to the plurality of common source lines CSL. Alternatively, the plurality of common source lines CSL may be electrically controlled independently from each other.

Each of the cell strings CSTR may include a ground selection transistor GST connected to the common source line CSL, a string selection transistor SST connected to the bit line BL, and a plurality of memory cell transistors MCT between the ground and string selection transistors GST and SST. The ground selection transistor GST, the plurality of memory cell transistors MCT, and the string selection transistor SST may be connected in series to each other.

The common source line CSL may be connected to sources of the ground selection transistors GST in common. A ground selection line GSL, a plurality of word lines WL0 to WL3, and a string selection line SSL, which are disposed between the common source line CSL and the bit line BL, may be used as gate electrodes of the ground selection transistor GST, the memory cell transistors MCT, and the string selection transistor SST, respectively. Each of the memory cell transistors MCI corresponds to a memory element.

FIG. 1B is a perspective view illustrating a structure of a 3D semiconductor memory device according to an exemplary embodiment of the inventive concept.

Referring to FIG. 1B, an electrode structure 115 may be disposed on a substrate 100. The electrode structure 115 may include insulating layers 111 and horizontal electrodes 150 that are alternately and repeatedly stacked on the substrate 100. The insulating layers 111 and the horizontal electrodes 150 may extend in a first direction. The electrode structure 115 may be provided in plural, and the plurality of electrode structures 115 may be arranged in a second direction crossing the first direction. The first and second directions may correspond to an x-axis direction and a y-axis direction of FIG. 1B, respectively. A trench 140 may be defined between the electrode structures 115 adjacent to each other. The trench 140 may extend in the first direction. As illustrated in FIG. 1B, the trenches 140 may be provided in plural. Common source lines CSL may be disposed in the substrate 100 exposed by the trenches 140, respectively. Each of the common source lines CSL may be a dopant region heavily doped with dopants. Isolation insulating layers (not shown) may fill the trenches 140, respectively.

Vertical structures 130 may penetrate the electrode structures 115 and be connected to the substrate 100. For example, the vertical structures 130 may be arranged in a matrix along the first and second directions in a plan view. A plurality of the vertical structures 130 may penetrate each of the electrode structures 115. In an exemplary embodiment of the inventive concept, the vertical structures 130 penetrating each of the electrode structures 115 may be arranged in a line along the first direction. In an exemplary embodiment of the inventive concept, the vertical structures 130 penetrating each of the electrode structures 115 may be arranged in a zigzag along the first direction. Each of the vertical structures 130 may include a data storage element S and a semiconductor pillar PL. In an exemplary embodiment of the inventive concept, the data storage element S may include a blocking insulating layer, a charge storage layer, and a tunnel insulating layer. Since the blocking insulating layer, the charge storage layer, and the tunnel insulating layer of the data storage element S are included in each of the vertical structures 130, a vertical scale of the 3D semiconductor memory device may be reduced. This will be described in more detail later. In an exemplary embodiment of the inventive concept, the semiconductor pillar PL may have a hollow tube-shape. In this case, the hollow region of the semiconductor pillar may be filled with a filling layer 128.

A drain region D may be disposed in an upper portion of the semiconductor pillar PL, and a conductive pattern 129 may be formed on the drain region D. A bit line BL may be electrically connected to the drain region D through the conductive pattern 129. The bit line BL may extend in a direction crossing the horizontal electrodes 150 (e.g., the second direction). In an exemplary embodiment of the inventive concept, the vertical structures 130 arranged in the second direction may be connected to one bit line BL.

Each of the horizontal electrodes 150 according to an exemplary embodiment of the inventive concept includes a gate electrode 145 and a metal stopper 123 disposed between the gate electrode 145 and the data storage element S. The metal stopper 123 may be in contact with the data storage element S. For example, the metal stopper 123 may include a conductive metal nitride (e.g., titanium nitride (TiN), tantalum nitride (TaN), and/or tungsten nitride (WN)). Since the metal stopper 123 includes a conductive material, the metal stopper 123 and the gate electrode 145 may function as a control gate of the 3D semiconductor memory device. Additionally, the metal stopper 123 may protect the data storage element S during a process of forming the gate electrode 145. This will be described in more detail later. The horizontal electrodes 150 may further include a barrier pattern 144 disposed between the metal stopper 123 and the gate electrode 145.

Hereinafter, a method of manufacturing a 3D semiconductor memory device according to an exemplary embodiment of the inventive concept will be described with reference to the attached drawings. Additionally, the 3D semiconductor memory device formed by the method will be described in more detail.

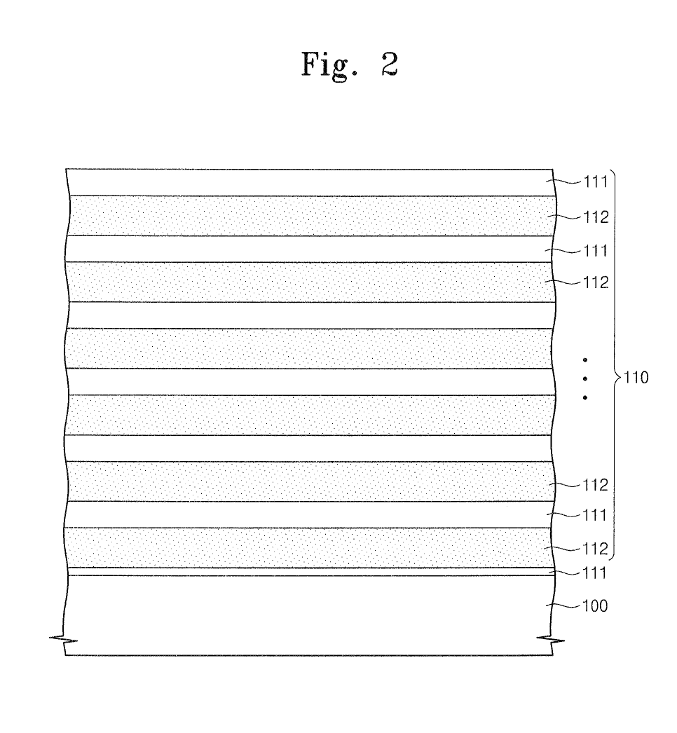

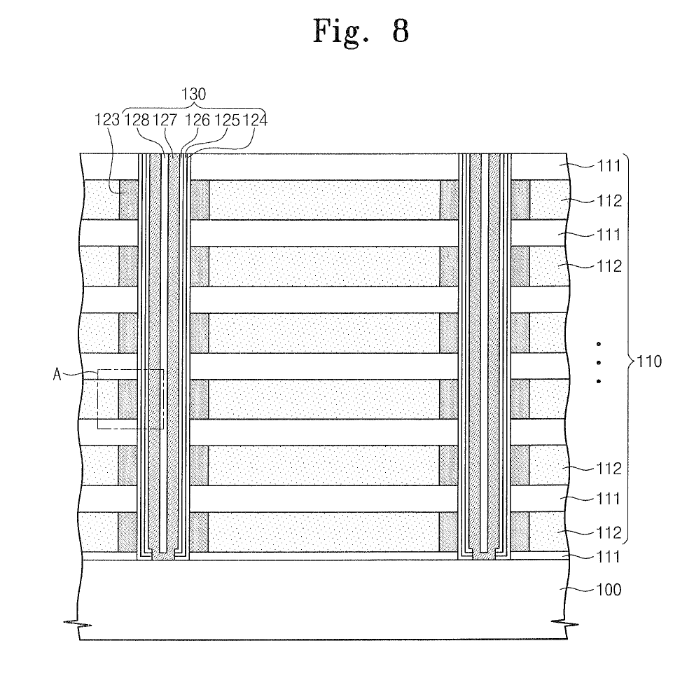

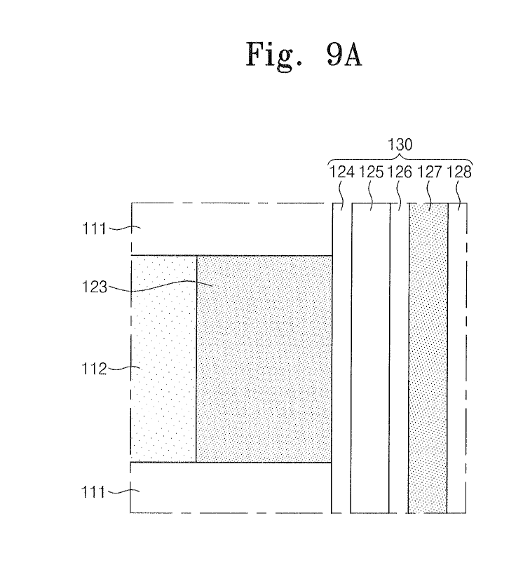

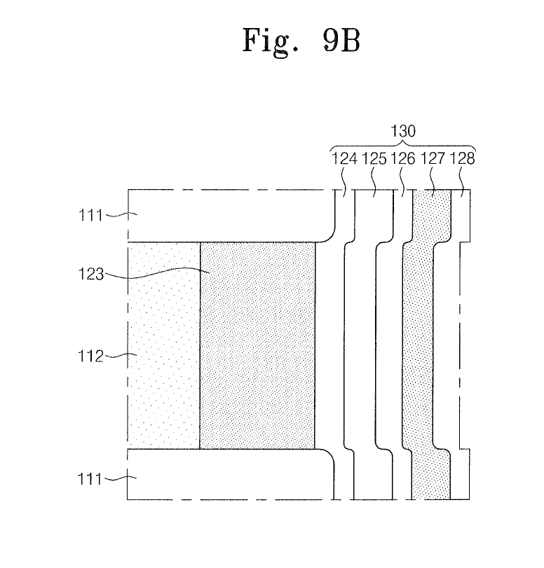

FIGS. 2 to 8 and 10 to 13 are cross-sectional views illustrating a method of manufacturing a 3D semiconductor memory device according to exemplary embodiments of the inventive concept. FIGS. 9A and 9B are enlarged views of a portion ‘A’ of FIG. 8.

Referring to FIG. 2, a mold stack structure 110 may be formed on a substrate 100.

The substrate 100 may be a material having semiconductor properties, an insulating material, a semiconductor covered by an insulating material or a conductor covered by an insulating material. For example, the substrate 100 may be a silicon wafer. In an exemplary embodiment of the inventive concept, dopants of a first conductivity type may be injected into the substrate 100 to form a well region (not illustrated).

The mold stack structure 110 may include a plurality of insulating layers 111 and a plurality of sacrificial layers 112. The insulating layers 111 and the sacrificial layers 112 may be alternately and repeatedly stacked on the substrate 100. The sacrificial layers 112 may be formed of a material having an etch selectivity with respect to the insulating layers 111. In other words, the sacrificial layers 112 may be formed of a material having an etch rate greater than that of the insulating layers 111 in a process of etching the sacrificial layers 112 according to a predetermined etch recipe. Each of the insulating layers 111 may include at least one of a silicon oxide layer and a silicon nitride layer. Each of the sacrificial layers 112 may include at least one of a silicon layer, a silicon oxide layer, a silicon carbide layer, and a silicon nitride layer. The material of the sacrificial layer 112 is different from that of the insulating layer 111. Hereinafter, the insulating layer 111 of the silicon oxide layer and the sacrificial layer 112 of the silicon nitride layer will be described as an example for convenience.

In an exemplary embodiment of the inventive concept, thicknesses of the sacrificial layers 112 may be substantially equal to each other. In an exemplary embodiment of the inventive concept, at least one of the sacrificial layers 112 may have a thickness different from other sacrificial layers 112. For example, a lowermost insulating layer of the insulating layers 111 may be thinner than the other insulating layers 111. However, the inventive concept is not limited thereto. The thicknesses of the insulating layers 111 may be variously changed.

Additionally, the number of layers constituting the mold stack structure 110 may be variously changed. In an exemplary embodiment of the inventive concept, the insulating layers 111 and the sacrificial layers 112 may be formed by a chemical vapor deposition (CVD) process. In an exemplary embodiment of the inventive concept, the lowermost insulating layer of the insulating layers 111 may be formed by a thermal oxidation process.

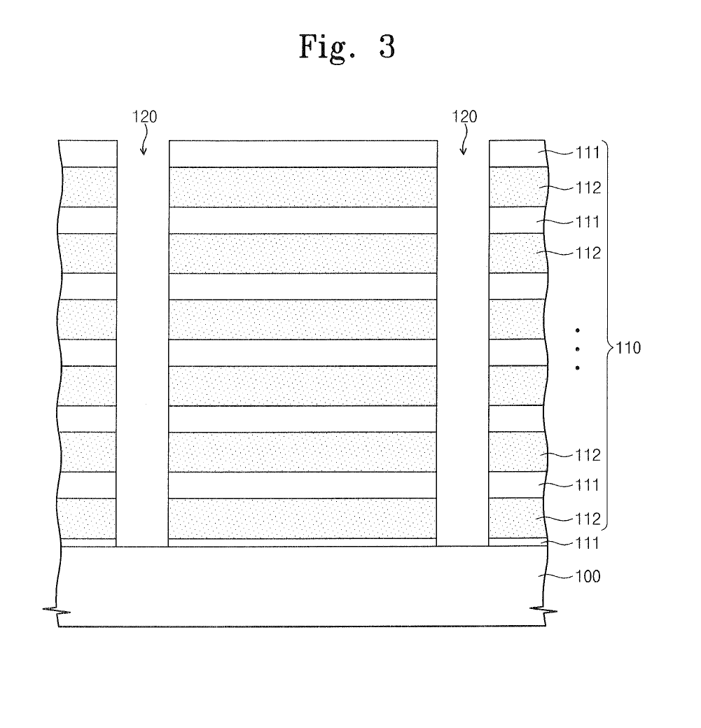

Referring to FIG. 3, through-holes 120 may be formed to penetrate the mold stack structure 110. The through-holes 120 may expose the substrate 100. Alternately stacked, the insulating layers 111 and the sacrificial layers 112 may be selectively and anisotropically etched to form the through-holes 120 exposing a top surface of the substrate 100. In a subsequent process, the aforementioned vertical structures 130 of FIG. 1B will be formed in the through-holes 120, respectively. Referring to FIGS. 1B and 2, the through-holes 120 may be arranged in a matrix along the first and second directions in a plan view. Alternatively, the through-holes 120 may be arranged in a zigzag along the first direction.

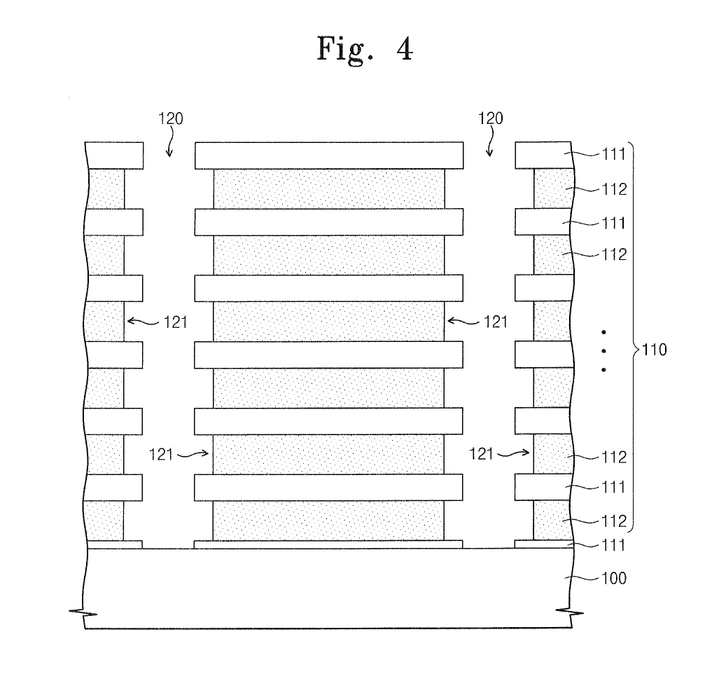

Referring to FIG. 4, some portions of the sacrificial layers 112 exposed by each of the through-holes 120 may be etched to form first recess regions 121. The portions of the sacrificial layers 112 may be selectively etched using the etch selectivity of the sacrificial layers 112 with respect to the insulating layers 111. Lateral depths of the first recess regions 121 may be controlled by controlling the etching process. As a result, the first recess regions 121 may have shapes laterally recessed from a sidewall of the through-hole 120. The first recess regions 121 may be defined as regions in which the metal stoppers 123 of FIG. 1B will be formed.

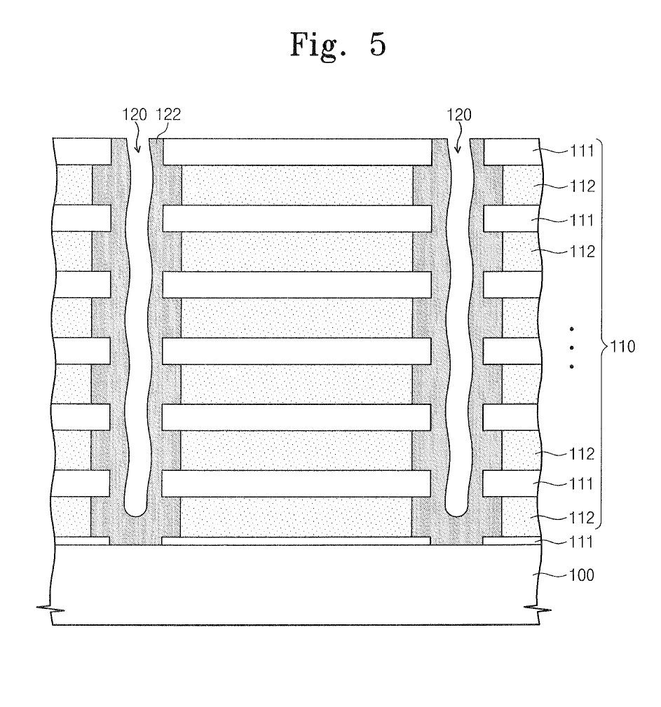

Referring to FIG. 5, a stopper material layer 122 may be formed to fill the first recess regions 121 of FIG. 4. The stopper material layer 122 may be conformally deposited along inner surfaces of the through-holes 120. In an exemplary embodiment of the inventive concept, the stopper material layer 122 may completely fill the first recess regions 121 and may partially fill the through-holes 120. For example, the stopper material layer 122 may include a metal, a metal silicide, or a doped semiconductor material. In an exemplary embodiment of the inventive concept, the stopper material layer 122 may include a conductive metal nitride. For example, the stopper material layer 122 may include titanium nitride (TiN), tantalum nitride (TaN), and/or a tungsten nitride (WN).

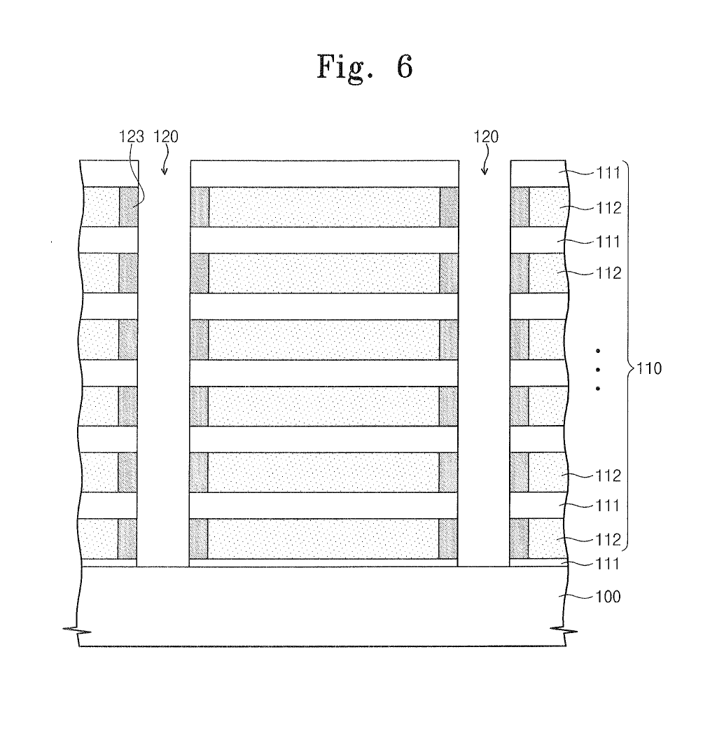

Referring to FIG. 6, the stopper material layer 122 of FIG. 5 may be etched to form a metal stopper 123. In an exemplary embodiment of the inventive concept, the stopper material layer 122 outside the first recess regions 121 of FIG. 4 (e.g., the stopper material layer 122 in the through-holes 120) may be isotropically etched and then removed to form the metal stopper 123. Thus, some portions of the deposited stopper material layer 122 may remain in the first recess regions 121 of FIG. 4, respectively. As a result, the metal stoppers 123 may be formed to be separated from each other.

In an exemplary embodiment of the inventive concept, the metal stopper 123 may completely fill the first recess regions 121, respectively. In this case, sidewalls of the vertical structures (130 of FIG. 1B) formed in a subsequent process may be substantially flat along sidewalls of the through-holes 120. In an exemplary embodiment of the inventive concept, the metal stopper 123 may partially fill the first recess regions 121. In other words, the stopper material layer 122 of FIG. 5 may be over-etched, such that the metal stopper 123 may partially fill the first recess regions 121. In this case, the vertical structures 130 of FIG. 1B in the through-holes 120 may fill the rest of the first recess regions 121. Thus, the vertical structures 130 of FIG. 1B may have uneven sidewalls. This will be described with reference to FIG. 9B in more detail.

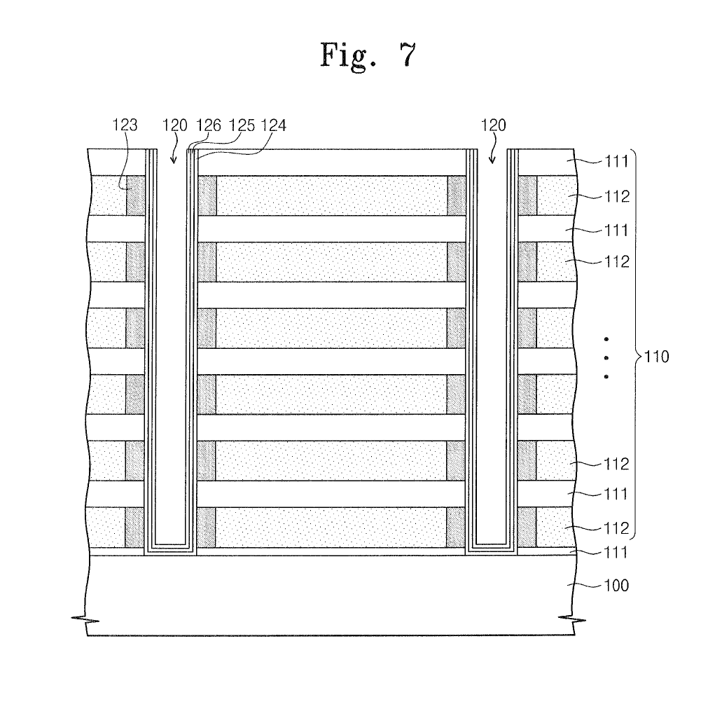

Referring to FIG. 7, a blocking insulating layer 124 may be formed in the through-holes 120. The blocking insulating layer 124 may be a single-layer or a multi-layer consisting of a plurality of thin layers. For example, the blocking insulating layer 124 may include an aluminum oxide layer and a silicon oxide layer. A stacking sequence of the aluminum oxide layer and the silicon oxide layer may be variously changed in the blocking insulating layer 124. The blocking insulating layer 124 may be in contact with the metal stopper 123 formed in the first recess regions 121 of FIG. 4. For example, the blocking insulating layer 124 may be formed by an atomic layer deposition (ALD) process.

A charge storage layer 125 may be formed on the blocking insulating layer 124. The charge storage layer 125 may include a charge trap layer and/or an insulating layer including conductive nano particles. For example, the charge trap layer may include a silicon nitride layer. A tunnel insulating layer 126 may be formed on the charge storage layer 125. The tunnel insulating layer 126 may be a single-layer or a multi-layer consisting of a plurality of thin layers. For example, each of the charge storage layer 125 and the tunnel insulating layer 126 may be formed by an ALD process. According to an exemplary embodiment of the inventive concept, the blocking insulating layer 124, the charge storage layer 125, and the tunnel insulating layer 126 may be formed in the through-holes 120 to reduce a vertical scale of the 3D semiconductor memory device.

Referring to FIGS. 8 and 9A, a semiconductor pillar 127 may be formed on the tunnel insulating layer 126 and in the through-holes 120. The semiconductor pillar 127 may be single-layered or multi-layered. In an exemplary embodiment of the inventive concept, a first semiconductor layer may be formed on the tunnel insulating layer 126, and then the first semiconductor layer and the layers 126, 125, and 124 disposed on a bottom surface of the through-holes 120 may be anisotropically etched to expose the substrate 100 under the through-holes 120. At this time, the first semiconductor layer on the sidewall of the through-holes 120 may remain. Subsequently, a second semiconductor layer may be formed on the remaining first semiconductor layer to form the semiconductor pillar 127. Each of the first and second semiconductor layers may be formed by an ALD process. The semiconductor pillar 127 may include amorphous silicon. In an exemplary embodiment of the inventive concept, an annealing process may be performed, such that the semiconductor pillar 127 may be converted into crystalline silicon.

In an exemplary embodiment of the inventive concept, the semiconductor pillar 127 may partially fill the through-holes 120, and then a filling layer 128 may be formed on the semiconductor pillar 127 to completely fill the through-holes 120. Thereafter, the filling layer 128 and the semiconductor pillar 127 may be planarized until the uppermost insulating layer 111 is exposed. As a result, the vertical structures 130 may be formed to include the blocking insulating layer 124, the charge storage layer 125, the tunnel insulating layer 126, the semiconductor pillar 127, and the filling layer 128 which are sequentially formed in the through-holes 120. In an exemplary embodiment of the inventive concept, the semiconductor pillar 127 may completely fill the through-holes 120, and the filling layer 128 may be omitted.

Referring to FIGS. 8 and 9B, in an exemplary embodiment of the inventive concept, the metal stopper 123 may be formed to partially fill the first recess regions 121 of FIG. 4. In this case, the blocking insulating layer 124 in the through-holes 120 may be conformally deposited in the rest the first recess regions 121 which are not filled with the metal stopper 123. Thus, the blocking insulating layer 124 may have an uneven shape as illustrated in FIG. 9B. As a result, the charge storage layer 125, the tunnel insulating layer 126, the semiconductor pillar 127, and the filling layer 128 sequentially formed on the blocking insulating layer 124 may also have uneven shapes.

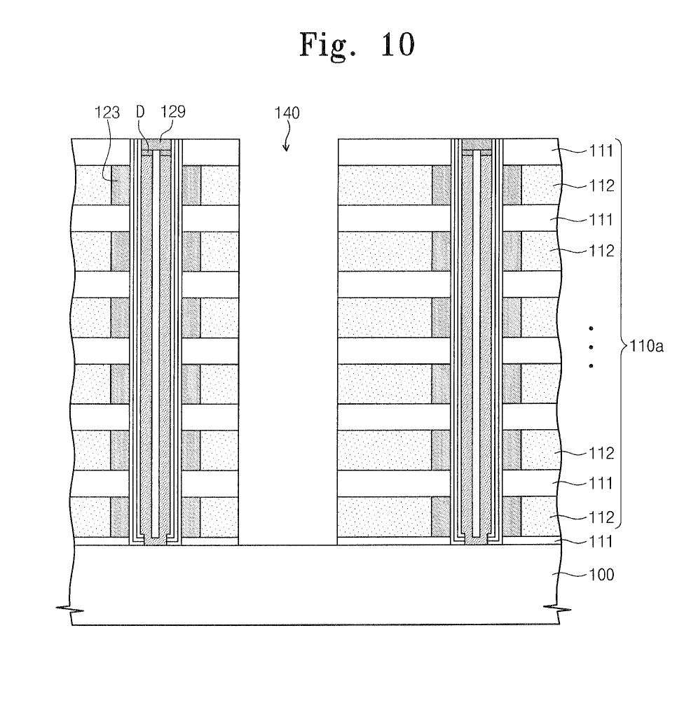

Referring to FIG. 10, a top surface of the semiconductor pillar 127 may be recessed to be lower than a top surface of the uppermost insulating layer 111. A conductive pattern 129 may be formed on the recessed semiconductor pillar 127 in the through-holes 120. The conductive pattern 129 may be formed of doped poly-silicon and/or a metal. Dopant ions may be implanted into the conductive pattern 129 and an upper portion of the recessed semiconductor pillar 127 to form a drain region D. For example, the dopants ions may be N-type dopant ions.

Trench 140 may be formed to divide the mold stack structure 110 into a plurality of mold stack patterns 110a. The trench 140 may be formed between the vertical structures 130. Forming the trench 140 may include successively patterning the insulating layers 111 and the sacrificial layers 112 to expose the substrate 100. The trench 140 may extend in the first direction (the x-axis direction of FIG. 1B), such that the mold stack structure 110 may be divided into the plurality of mold stack patterns 110a. As a result, the plurality of mold stack patterns 110a may be separated from each other in the second direction (the y-axis direction of FIG. 1B).

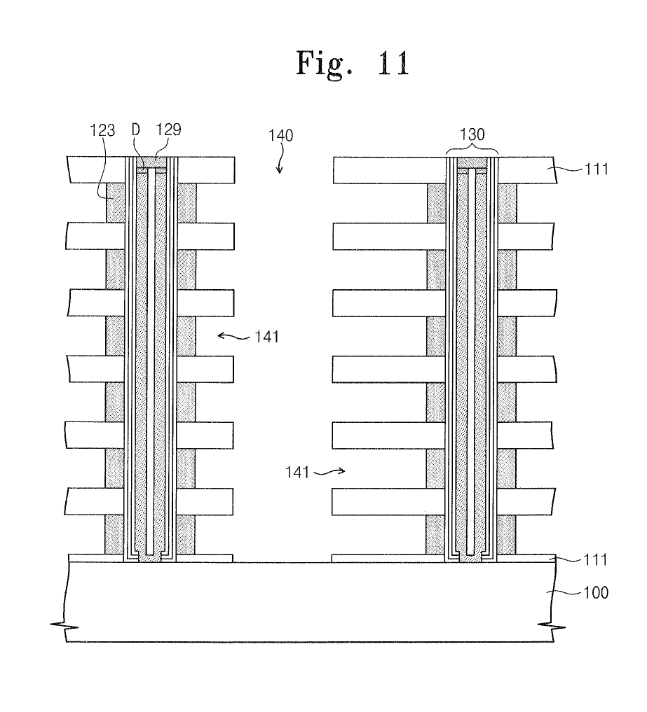

Referring to FIG. 11, the sacrificial layers 112 exposed by the trench 140 may be removed to form second recess regions 141. The second recess regions 141 correspond to regions formed by removing the sacrificial layers 112 of the mold stack pattern 110a. The second recess regions 141 are defined by the vertical structures 130 and the insulating layers 111. For example, if the sacrificial layers 112 are formed of silicon nitride and/or silicon oxynitride, the sacrificial layers 112 may be removed by an etching solution including phosphoric acid.

Forming the second recess regions 141 may include etching the sacrificial layers 112 until the metal stoppers 123 are exposed. Since the metal stoppers 123 have an etch selectivity with respect to the sacrificial layers 112, the sacrificial layers 112 may be removed and then the metal stoppers 123 may remain and be exposed. In this process, the metal stoppers 123 may protect the vertical structures 130. In other words, the metal stoppers 123 may prevent the vertical structures 130 from being damaged by the etching solution during the removal of the sacrificial layers 112.

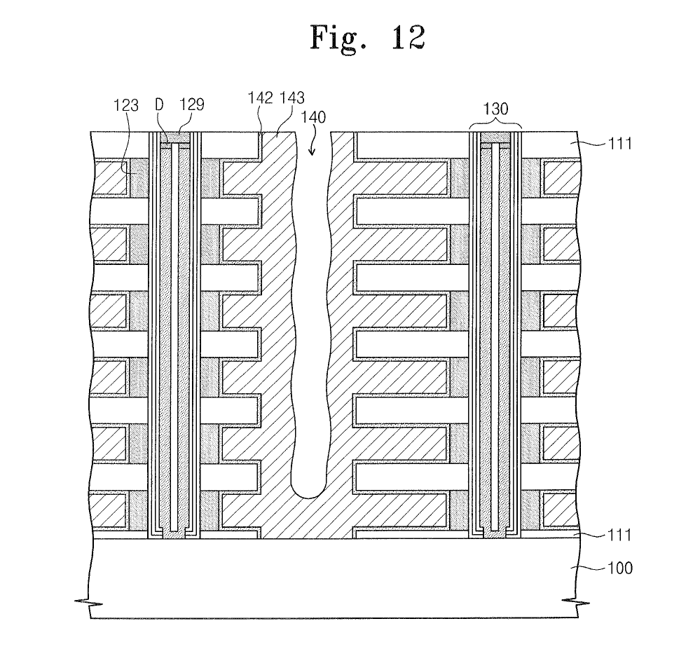

Referring to FIG. 12, a barrier layer 142 and an electrode layer 143 may be sequentially formed to fill the second recess regions 141 of FIG. 11. The barrier layer 142 and the electrode layer 143 may be conformally deposited along inner surfaces of the second recess regions 141 and the trench 140. In an exemplary embodiment of the inventive concept, the barrier layer 142 and the electrode layer 143 may completely fill the second recess regions 141 of FIG. 11 and may partially fill the trench 140. In an exemplary embodiment of the inventive concept, the electrode layer 143 may include a metal (e.g., tungsten), and the barrier layer 142 may include a metal nitride (e.g., TiN, TaN, and/or WN). In an exemplary embodiment of the inventive concept, the electrode layer 143 may include doped poly-silicon. In this case, the barrier layer 142 may be omitted.

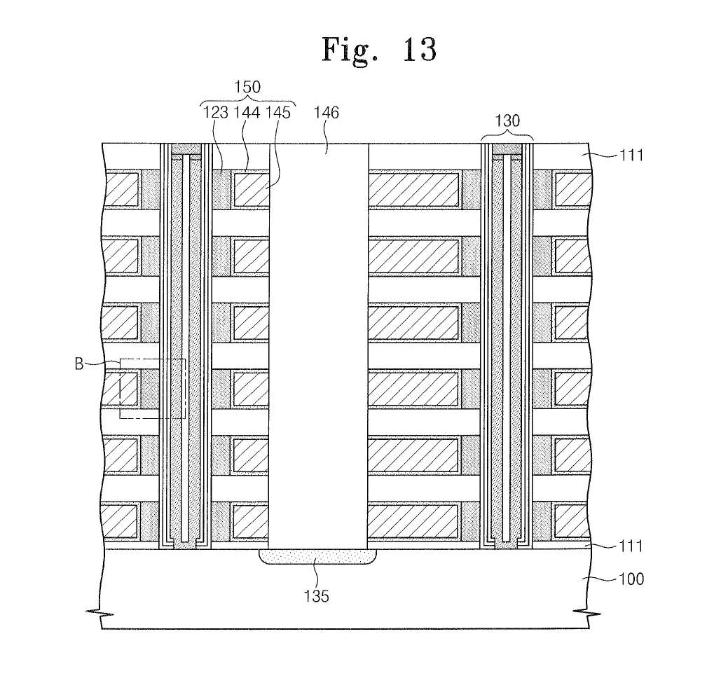

Referring to FIG. 13, the barrier layer 142 and the electrode layer 143 outside the second recess regions 141 may be removed. For example, the barrier layer 142 and the electrode layer 143 outside the second recess regions 141 may be removed by an isotropic etching process. Thus, a barrier pattern 144 and a gate electrode 145 are locally formed in each of the second recess regions 141. As a result, each of the horizontal electrodes 150 including the metal stopper 123, the barrier pattern 144, and the gate electrode 145 may be formed. In an exemplary embodiment of the inventive concept, the barrier pattern 144 may be omitted.

Subsequently, dopant ions may be heavily implanted into the substrate 100 under the trench 140 to form a dopant region 135. The dopant region 135 may be defined as the common source line CSL of FIG. 1A or FIG. 1B. An isolation insulating layer 146 may be formed to fill the trench 140 of FIG. 12. The isolation insulating layer 146 may extend along the trench 140 in the first direction. Thereafter, the bit line BL may be formed to be connected in common to the vertical structures 130 arranged in the second direction as illustrated in FIG. 1B.

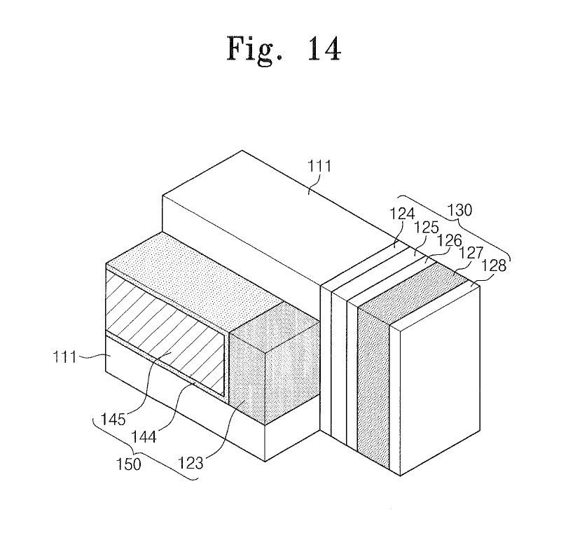

FIG. 14 is a perspective view illustrating the horizontal electrode 150 and the vertical structures 130 according to an exemplary embodiment of the inventive concept. FIG. 14 is an enlarged-perspective view of a portion ‘B’ of FIG. 13.

Referring to FIG. 14, according to an exemplary embodiment of the inventive concept, the metal stopper 123 is disposed between the blocking insulating layer 124 and the gate electrode 145. The metal stopper 123 prevents the blocking insulating layer 124 from being etched during the process of removing the sacrificial layers 112, such that the vertical structures 130 may be protected by the metal stopper 123. The barrier pattern 144 may be disposed between the metal stopper 123 and the gate electrode 145. In this case, the metal stopper 123, the barrier pattern 144, and the gate electrode 145 may constitute one of the horizontal electrodes 150. However, all of the horizontal electrodes 150 may be made of these elements. The horizontal electrodes 150 may be formed by a conductive material including a metal, to function as the control gate of the 3D semiconductor memory device.

3D semiconductor memory devices according to exemplary embodiments of the inventive concept may be encapsulated using various packaging techniques. For example, 3D semiconductor memory devices according to exemplary embodiments of the inventive concept may he encapsulated using any one of a package on package (POP) technique, a ball grid array (BGA) technique, a chip scale package (CSP) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline integrated circuit (SOIC) technique, a shrink small outline package (SSOP) technique, a thin small outline package (TSOP) technique, a thin quad flat package (TQFP) technique, a system in package (SIP) technique, a multi chip package (MCP) technique, a wafer-level fabricated package (WFP) technique and a wafer-level processed stack package (WSP) technique.

The package in which the 3D semiconductor memory device according to exemplary embodiments of the inventive concept is mounted may further include at least one semiconductor device (e.g., a controller and/or a logic device) that controls the 3D semiconductor memory device.

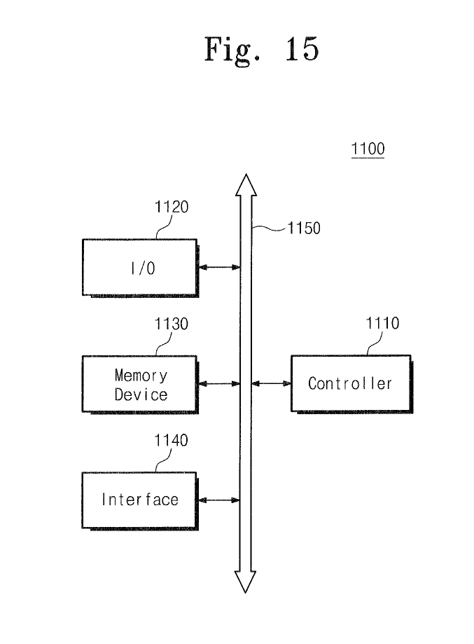

FIG. 15 is a block diagram illustrating an electronic system including a 3D semiconductor memory device according to an exemplary embodiment of the inventive concept.

Referring to FIG. 15, an electronic system 1100 according to an exemplary embodiment of the inventive concept may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller or other logic devices. The other logic devices may have a similar function to any one of the microprocessor, the digital signal processor and the microcontroller. The I/O unit 1120 may include a keypad, a keyboard and/or a display unit. The memory device 1130 may store data and/or commands. The memory device 1130 may include a 3D semiconductor memory device according to an exemplary embodiment of the inventive concept. The memory device 1130 may further include another type of semiconductor memory device (e.g., a non-volatile memory device and/or a static random access memory (SRAM) device) which is different from a 3D semiconductor memory device according to an exemplary embodiment of the inventive concept. The interface unit 1140 may transmit electrical data to a communication network or may receive electrical data from a communication network. The interface unit 1140 may operate wirelessly or by cable. For example, the interface unit 1140 may include an antenna for wireless communication or a transceiver for cable communication. Although not shown in the drawings, the electronic system 1100 may further include a fast dynamic random access memory (DRAM) device and/or a fast SRAM device which acts as a cache memory for improving an operation of the controller 1110.

The electronic system 1100 may be applied to a personal digital assistant (PDA), a portable computer, a web tablet, a wireless phone, a mobile phone, a digital music player, a memory card or other electronic products. The other electronic products may receive or transmit information wirelessly.

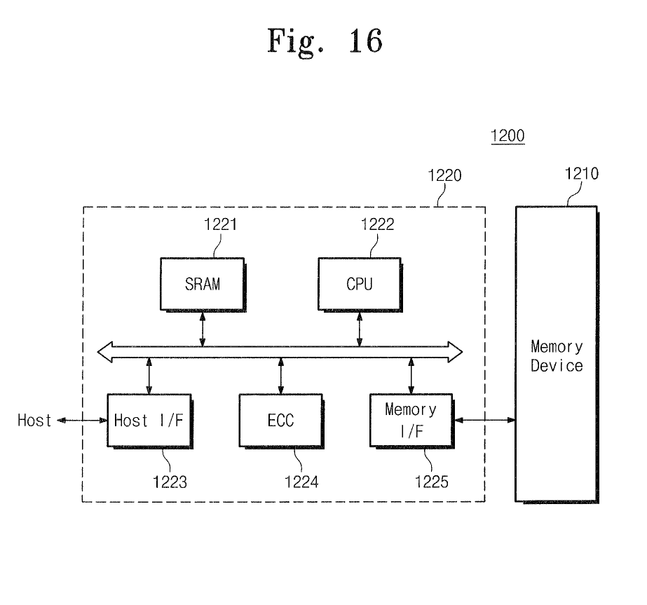

FIG. 16 is a block diagram illustrating a memory card including a 3D semiconductor memory device according to an exemplary embodiment of the inventive concept.

Referring to FIG. 16, a memory card 1200 according to an exemplary embodiment of the inventive concept may include a memory device 1210. The memory device 1210 may include a 3D semiconductor memory device according to an exemplary embodiment of the inventive concept. In an exemplary embodiment of the inventive concept, the memory device 1210 may further include another type of semiconductor memory device (e.g., a non-volatile memory device and/or a SRAM device) which is different from a 3D semiconductor device according to an exemplary embodiment of the inventive concept. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may realized as a solid state disk (SSD) which is used as a hard disk of a computer system.

According to an exemplary embodiment of the inventive concept, the data storage element including the blocking insulating layer, the charge storage layer, and the tunnel insulating layer is included in the vertical structure formed in the through-hole. Thus, the vertical scale of the 3D semiconductor memory device may be reduced.

According to an exemplary embodiment of the inventive concept, the metal stopper is disposed between the blocking insulating layer and the gate electrode. The metal stopper prevents the blocking insulating layer from being etched during the process of removing the sacrificial layers. Thus, the vertical structure including the blocking insulating layer may be protected by the metal stopper.

According to an exemplary embodiment of the inventive concept, since the metal stopper is formed of the conductive material including a metal, the metal stopper and the gate electrode may function as the control gate of the 3D semiconductor memory device.

While the inventive concept has been shown and described with reference to example embodiments thereof, it will be apparent to those of ordinary skill in the art that various changes in form and detail may be made thereto without departing from the spirit and scope of the inventive concept as defined by the following claims.

1. A three-dimensional semiconductor memory device, comprising:
an electrode structure including insulating patterns and horizontal electrodes stacked on a substrate, the electrode structure extending in a first direction;
a semiconductor pillar penetrating the electrode structure and connected to the substrate;
a charge storage layer between the semiconductor pillar and the electrode structure;
a tunnel insulating layer between the charge storage layer and the semiconductor pillar; and
a blocking insulating layer between the charge storage layer and the electrode structure, wherein a first horizontal electrode of the horizontal electrodes includes a gate electrode and a metal stopper between the gate electrode and the blocking insulating layer.

2. The three-dimensional semiconductor memory device of claim 1, wherein the electrode structure is provided in plural;
wherein a trench extending in the first direction is between the plurality of electrode structures, and the plurality of electrode structures are spaced apart from each other in a second direction crossing the first direction.

3. The three-dimensional semiconductor memory device of claim 2, further comprising:
an isolation insulating layer filling the trench between the plurality of electrode structures.

4. The three-dimensional semiconductor memory device of claim 1, wherein the tunnel insulating layer, the charge storage layer, and the blocking insulating layer extend vertically from the substrate.

5. The three-dimensional semiconductor memory device of claim 1, wherein the metal stopper is in contact with the blocking insulating layer.

6. The three-dimensional semiconductor memory device of claim 1, wherein the metal stopper includes a conductive metal nitride.

7. The three-dimensional semiconductor memory device of claim 1, wherein the gate electrode includes a metal.

8. The three-dimensional semiconductor memory device of claim 1, wherein the first horizontal electrode further includes a barrier pattern between the metal stopper and the gate electrode.

9. The three-dimensional semiconductor memory device of claim 1, wherein the semiconductor pillar has a tube-shape, and is filled with a filling layer.

10. The three-dimensional semiconductor memory device of claim 1, wherein the insulating patterns and the horizontal electrodes are alternately and repeatedly stacked on the substrate.

11-16. (canceled)

17. A three-dimensional semiconductor memory device, comprising:
a first insulating layer and a second insulating layer disposed on a substrate;
a gate electrode and a metal stopper disposed between the first and second insulating layers; and
a blocking insulating layer, a charge storage layer, a tunnel insulating layer and a semiconductor pillar disposed in sequence, wherein the blocking insulating layer is adjacent to the metal stopper.

18. The three-dimensional semiconductor memory device of claim 17, wherein the blocking insulating layer extends from the first insulating layer to the second insulating layer.

19. The three-dimensional semiconductor memory device of claim 17, wherein a barrier layer is formed between the metal stopper and the gate electrode.

20. The three-dimensional semiconductor memory device of claim 17, wherein the blocking insulating layer, the charge storage layer and the tunnel insulating layer form a data storage element.
